(19) United States
(12) Patent Application Publication
(10) Pub. No.: US 2026/0305208 A1
(43) Pub. Date: Oct. 1, 2026

(54) METHODS FOR REDUCING CRITICAL DIMENSION VARIATION

(71) Applicant: Tokyo Electron Limited, Tokyo (JP)

(72) Inventors: Emilia Hirsch, Albany, NY (US); Peng Wang, Albany, NY (US)

(21) Appl. No.: 19/096,984

(22) Filed: Apr. 1, 2025

(51) Int. Cl. H01L 21/311

(52) U.S. Cl. CPC H10P 50/73; H10P 50/283; H10P 50/287

(57) ABSTRACT

A method is provided for processing a substrate to improve local critical dimension uniformity. The method includes providing a substrate in a process chamber, the substrate including a layer to-be-etched, a planarization layer over the layer to-be-etched, and a pattern transfer layer over the planarization layer. A plurality of openings are formed through the pattern transfer layer and the planarization layer, including a first opening with a first width and a second opening with a second width, the first width being different from the second width. A process gas is flowed in the process chamber and a radio frequency source power is applied to generate a plasma. The pattern transfer layer is bombarded with the plasma to form a modified surface layer that differentially seals top portions of the openings based on width differences. The modified surface layer is etched to expose the second opening while maintaining a seal over the first opening. The etching continues to increase the second width to a third width, reducing the dimensional difference between openings.

### TECHNICAL FIELD

The present invention relates generally to a method for semiconductor device manufacturing, and, in particular embodiments, to a method for reducing critical dimension variation in semiconductor devices.

### BACKGROUND

In the realm of semiconductor fabrication, integrated circuits (ICs) are created through a methodical process of depositing and patterning successive layers of dielectric, conductive, and semiconductor materials atop a semiconductor substrate. This intricate fabrication employs photolithography and etching techniques to construct the various structures required for circuit components and interconnections, including transistors, resistors, capacitors, metal lines, contacts, and vias. As the industry progresses to more advanced technology nodes, feature dimensions are reduced to approximately double the component density with each generation.

A primary approach to achieving finer resolution patterns involves shortening the wavelength of the illumination source. The 248 nm deep ultraviolet (DUV) radiation from KrF lasers, once used for critical patterning at 250 nm and 130 nm nodes, was superseded by 193 nm ArF lasers beginning with the 90 nm node. Through resolution enhancement methods such as immersion lithography, features as small as 35 nm can be patterned using 193 nm lithography. While 193 nm optical systems have been extended to 14 nm and even 10 nm nodes through multiple patterning approaches, these advancements come with increased costs and process complexity due to additional masking steps. In sub-10 nm applications, DUV may be replaced by extreme ultraviolet (EUV) technology with its 13.5 nm wavelength. Although EUV offers potential for higher resolution with fewer masks, it faces integration challenges across all lithography system components. A significant concern is that resists exposed to EUV radiation exhibit sensitivity to stochastic effects, causing unpredictable failures when patterning extremely small features in sub-10 nm designs. These stochastic effects can increase local critical dimension uniformity (LCDU) variations in interconnect elements, potentially impacting device performance as feature sizes and edge placement error margins continue to shrink with each technology advancement.

### SUMMARY

In accordance with one aspect of the present invention, a method is provided for processing a substrate. The method includes providing a substrate in a process chamber, the substrate comprising a layer to-be-etched, a planarization layer disposed over the layer to-be-etched, and a pattern transfer layer disposed over the planarization layer. A plurality of openings are formed through the pattern transfer layer and the planarization layer, the plurality of openings comprising a first opening with a first width and a second opening with a second width, the first width being different from the second width. A process gas is flowed in the process chamber and a radio frequency (RF) source power is applied to generate a plasma from the process gas. The pattern transfer layer is bombarded with the plasma to form a modified surface layer that differentially seals top portions of the first and the second openings based on a difference between the first width and the second width. The modified surface layer is etched to expose the second opening while maintaining a seal over the first opening. The etching is continued to increase the second width of the second opening to a third width, wherein a difference between the third width and the first width is less than a difference between the second width and the first width.

In accordance with another aspect of the present invention, a method is provided for processing a substrate. The method includes providing a substrate comprising a pattern transfer layer disposed over a planarization layer, wherein the pattern transfer layer and the planarization layer comprise a first opening and a second opening extending through, the first opening comprising a first width and the second opening comprising a second width, wherein the first width is greater than the second width. A coating layer is formed over the pattern transfer layer, wherein the coating layer differentially seals top portions of the first and the second openings, and wherein a depth of the coating layer in the first opening is greater than a depth of the coating layer in the second opening. Portions of the coating layer are removed to expose the second opening while maintaining a seal over the first opening. The removing is continued to increase the second width of the second opening to a third width, wherein a difference between the third width and the first width is less than a difference between the second width and the first width.

In accordance with yet another aspect of the present invention, a method is provided for processing a substrate. The method includes loading a substrate in a process chamber, the substrate comprising a pattern transfer layer disposed over a planarization layer, wherein the pattern transfer layer and the planarization layer comprise a first opening and a second opening extending through, the first opening comprising a first width and the second opening comprising a second width. A process gas comprising an inert gas is flowed into the process chamber. Cyclic power pulses are applied to power electrodes in the process chamber to generate a plasma from the process gas. The pattern transfer layer is bombarded with the plasma to differentially seal top portions of the first and the second openings based on a difference between the first width and the second width. The pattern transfer layer is etched to expose the second opening while maintaining a seal over the first opening. The etching is continued to increase the second width of the second opening to a third width.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1I illustrate cross-sectional views of a method for improving local critical dimension uniformity (LCDU) using plasma bombardment based vertical loading process, in accordance with an embodiment;

FIGS. 2A-2I illustrate top views corresponding to the cross-sectional views of FIGS. 1A-1I, in accordance with an embodiment;

FIGS. 3A-3B illustrate cross-sectional views of an alternative embodiment using deposition based vertical loading process, in accordance with an embodiment;

FIGS. 4A-4B illustrate top views corresponding to the cross-sectional views of FIGS. 3A-3B, in accordance with an embodiment;

FIGS. 5A-5B illustrate timing diagrams for bias power and source power during plasma bombardment, in accordance with an embodiment;

FIG. 6 illustrates experimental data showing reduced LCDU using vertical loading, in accordance with an embodiment;

FIG. 7 illustrates a process flow diagram for improving LCDU using plasma bombardment based vertical loading process, in accordance with an embodiment; and

FIG. 8 illustrates another process flow diagram for improving LCDU using layer deposition based vertical loading process, in accordance with an embodiment.

### DETAILED DESCRIPTION OF ILLUSTRATIVE EMBODIMENTS

In back-end-of-line and middle-of-line processes, maintaining tight LCDU for vias and contact holes is particularly challenging due to their small size and high aspect ratios. Conventional approaches to improve LCDU often involve lateral loading techniques, which may introduce issues such as material build-up on alignment marks and potential for missing contacts.

Embodiments of the present disclosure relate to methods for improving local critical dimension uniformity (LCDU) in semiconductor device manufacturing. In various embodiments, a vertical loading process leverages the differential deposition characteristics in openings of different widths to reduce critical dimension variation between features. The process, in various embodiments, may include a bombardment or deposition process to encapsulate the openings. In various embodiments, the encapsulating may differentially seal the top portions of different openings, with larger openings having deeper sealing depths than smaller openings due to aspect ratio effects. The process may utilize plasma bombardment, such as with argon or other inert gases, to preferentially seal top portions of features. This differential sealing creates an opportunity to selectively expose smaller openings first during a subsequent removal process. In one or more embodiments, the removal process may first expose the smaller openings while maintaining the seal over larger openings, allowing the smaller openings to be widened through continued processing. This selective processing results in reducing the width difference between smaller and larger openings, thereby improving LCDU.

In various embodiments, the vertical loading process may offer advantages over conventional lateral loading techniques, including reduced material build-up on alignment marks, decreased risk of missing contacts, and improved pattern fidelity. The process may be applied to various semiconductor manufacturing contexts, including back-end-of-line (BEOL) via formation and middle-of-line (MOL) contact hole creation. By reducing LCDU, aspects of the disclosure help minimize edge placement errors and improve device performance and yield in advanced semiconductor nodes. These and additional details are further discussed below.

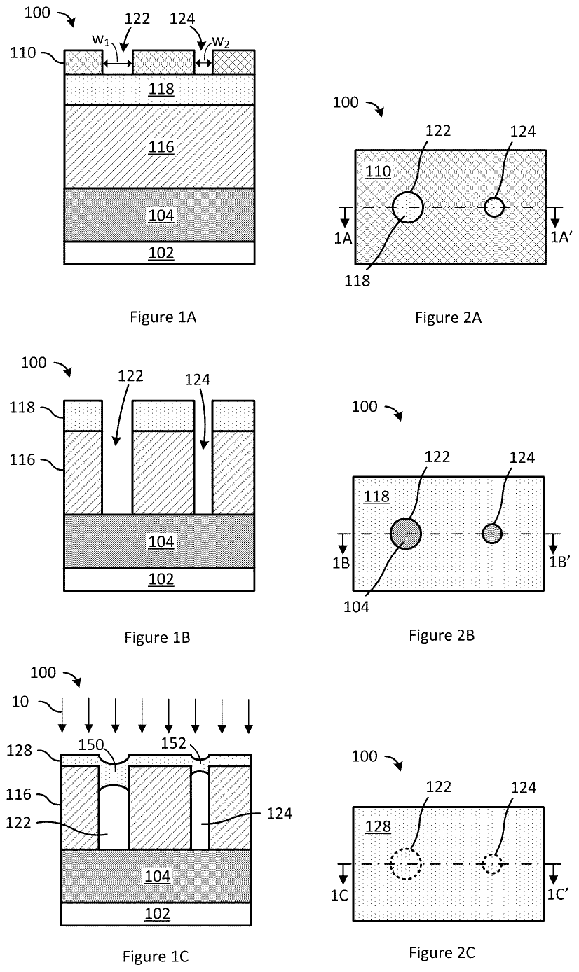

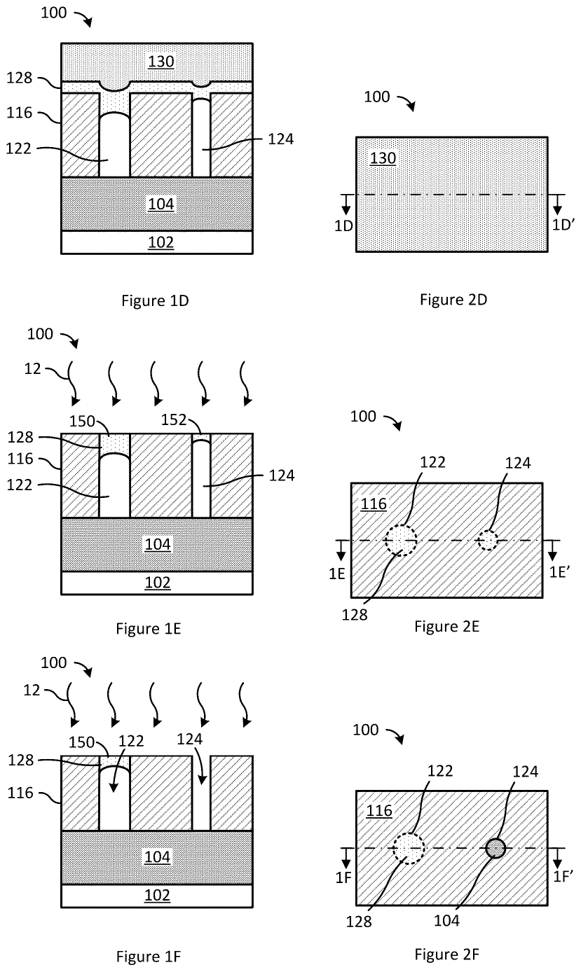

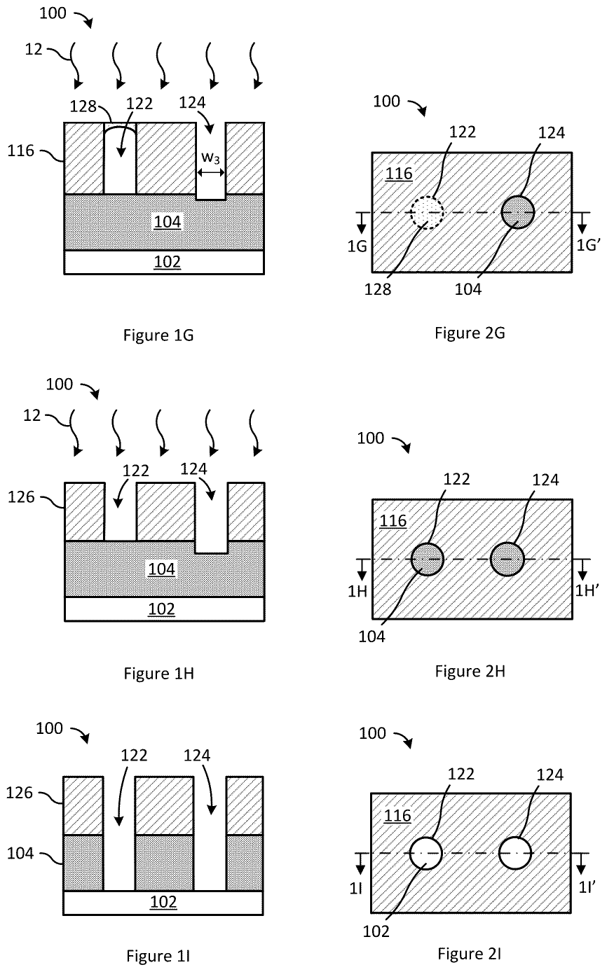

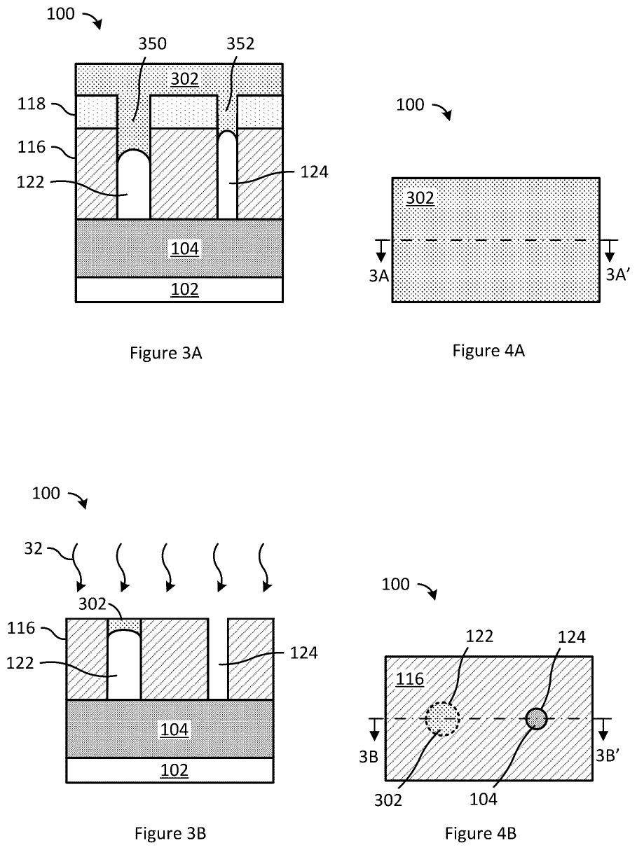

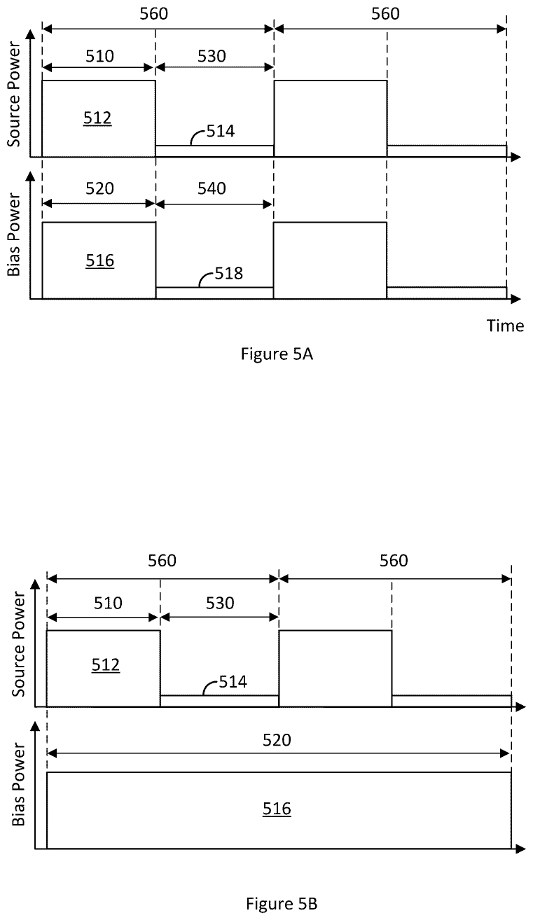

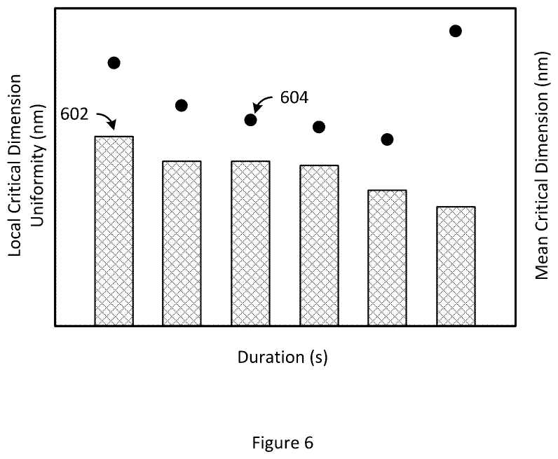

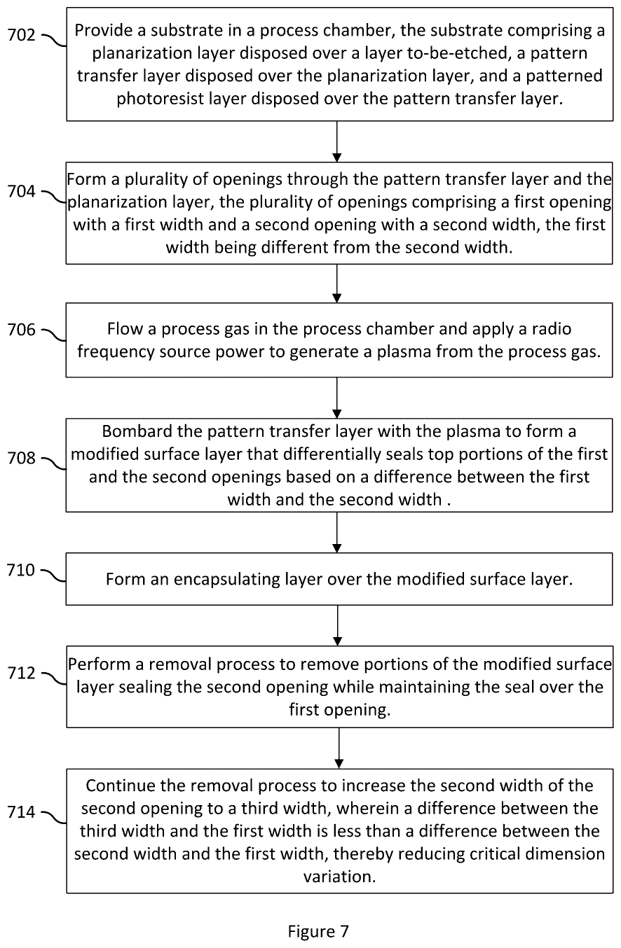

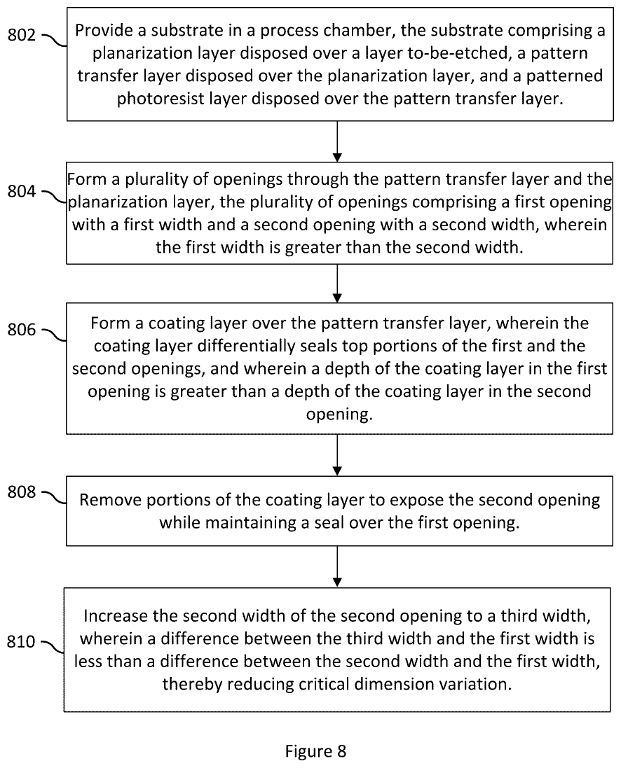

Embodiments of the disclosure are described in the context of the accompanying drawings. An embodiment of a process flow for improving local critical dimension uniformity (LCDU) using bombardment based vertical loading process is illustrated in FIGS. 1A-1I and 2A-2I. An alternative embodiment using deposition based vertical loading process is shown in FIGS. 3A-3B and 4A-4B. Timing diagrams for applied powers during bombardment are presented in FIGS. 5A-5B, showing the relationship between bias power and source power pulses. Experimental data demonstrating LCDU reduction through the vertical loading process is illustrated in FIG. 6, showing the relationship between process duration and critical dimension uniformity. Process flow diagrams showing the steps of two vertical loading processes for LCDU improvement are presented in FIGS. 7 and 8.

FIGS. 1A-1I and 2A-2I illustrate cross-sectional views and corresponding top views of a method for improving local critical dimension uniformity (LCDU), respectively, in accordance with an embodiment.

FIG. 1A illustrates a cross-sectional view of a substrate 100 (along line 1A-1A′ in FIG. 2A) loaded in a process chamber. The substrate 100 may comprise multiple layers forming a processing stack: a substrate layer 102, a layer to-be-etched 104, a planarization layer 116, a pattern transfer layer 118, and a patterned photoresist layer 110.

In various embodiments, the substrate layer 102 may comprise silicon, silicon-on-insulator (SOI), or other semiconductor materials that serve as the foundation for device fabrication. The substrate layer 102 may also be coated or layered with any number of additional materials, including compound semiconductors, metal or metal oxides, or metal nitrides. The substrate layer 102 may include any material portion or structure of a device, particularly a semiconductor or other electronics device.

The layer to-be-etched 104 may be disposed over the substrate layer 102. In various embodiments, the layer to-be-etched 104 may comprise a dielectric material such as silicon nitride (SiN), silicon oxide (SiO₂), or other materials targeted for patterning.

The planarization layer 116 may be disposed over the layer to-be-etched 104 and comprise an organic material such as an organic planarization layer (OPL), amorphous carbon layer (ACL), or spin-on carbon (SOC). The planarization layer 116 may planarize underlying topography, provides a uniform surface for subsequent processes, and function as a sacrificial layer for high-aspect-ratio pattern transfer. The planarization layer 116 may also offer good etch selectivity relative to the underlying layer to-be-etched 104.

The pattern transfer layer 118 may be disposed over the planarization layer 116 and comprise bottom anti-reflective coating (BARC) such as silicon anti-reflective coating (SiARC) or organic anti-reflective coating, low temperature oxide (LTO), or the like. The pattern transfer layer 118 may function as an anti-reflective coating to reduce light reflection during lithography and serve as a hard mask for pattern transfer to underlying layers. The pattern transfer layer 118 may provide etch selectivity relative to the planarization layer 116 and help control critical dimensions during the patterning process.

In one or more embodiments, the patterned photoresist layer 110 may be disposed over the pattern transfer layer 118 and formed through a lithography process. To create the patterned photoresist layer 110, a photoresist material may be first deposited over the pattern transfer layer 118 using spin coating. The photoresist material may be then exposed to radiation (such as DUV or EUV) through a photomask containing the desired pattern. For positive photoresists, the exposed regions become soluble in the developer solution, while for negative photoresists, the exposed regions become insoluble. After exposure, the substrate 100 may undergo a development process where either the exposed (for positive resist) or unexposed (for negative resist) portions are dissolved away, creating the patterned photoresist layer 110.

In various embodiments, the patterned photoresist layer 110 may comprise a first opening 122 with a first width w₁ and a second opening 124 with a second width w₂, where the first width w₁ may be different from the second width w₂. In some embodiments, the first width w₁ may be greater than the second width w₂. This width difference may result from various factors including mask design, lithography limitations, or stochastic effects during exposure and development. The difference in opening widths represents the local critical dimension variation that the subsequent vertical loading process aims to reduce.

In various embodiments, LCDU quantifies the variation in critical dimensions within a localized area, representing statistical spread of a CD distribution across features such as vias or contact holes. LCDU may be mathematically defined as three times the standard deviation of the critical dimension measurements, calculated using the Equation 1:

$$L C D U = 3 \times \sqrt{\frac{\sum {( C {D}_{i} - \overline{C D} )}^{2}}{N}} \qquad ( Equation 1 )$$

where CDᵢ represents individual critical dimension measurements, C̅D̅ is the mean critical dimension, and N is the number of measurements.

In FIG. 1A, the first width w₁ and the second width w₂ may be individual CDᵢ values in Equation 1, with the mean critical dimension C̅D̅ being the average of all measured widths. The larger the difference between the first width w₁ and the second width w₂, the greater the standard deviation and resulting LCDU value. Higher LCDU indicates poorer uniformity, which may lead to open or short circuits during processes such as metallization. The vertical loading process described with reference to subsequent figures aims to reduce this difference between the first width w₁ and the second width w₂ by selectively increasing w₂ to be closer to w₁, which may reduce the spread of the CD distribution, thereby improving LCDU.

FIG. 2A illustrates a top view corresponding to the cross-sectional view shown in FIG. 1A, in accordance with an embodiment. This top-down perspective provides a planar view of the substrate 100 which shows the patterned photoresist layer 110. FIG. 2A shows the first opening 122 and the second opening 124 exposing a top surface of the pattern transfer layer 118.

FIGS. 1B and 2B illustrate cross-sectional and top views, respectively, of the substrate 100 after an etching process has been applied to extend the first opening 122 and the second opening 124 through the pattern transfer layer 118 and planarization layer 116, exposing a top surface of the layer to-be-etched 104. FIG. 1B is the cross-sectional view along the line 1B-1B′ in FIG. 2B. The etching process may transfer the pattern originally defined in the patterned photoresist layer 110 into the underlying layers.

During the etching process, the patterned photoresist layer 110 may serve as an etch mask for pattern transfer. The etching may be performed using various techniques suitable for high-aspect-ratio feature formation, including reactive ion etching (RIE), inductively coupled plasma (ICP) etching, capacitively coupled plasma (CCP) etching, electron cyclotron resonance (ECR) plasma etching, deep reactive ion etching (DRIE), atomic layer etching (ALE), wet etching processes using acid or base solutions, vapor phase etching, or combinations thereof. The specific etching chemistry and parameters are selected based on the materials being etched and the desired profile characteristics. In various embodiments, the patterned photoresist layer 110 may be removed during the etching process. FIGS. 1C and 2C illustrate cross-sectional and top views, respectively, of the substrate 100 after a vertical loading process. In FIG. 1C, a plasma 10 may be generated in the process chamber containing the substrate 100. In various embodiments, the plasma generation process may involve flowing a process gas into the process chamber and applying power to electrodes to ionize the gas. The process gas may comprise an inert gas such as argon, helium, neon, krypton, xenon, nitrogen, carbon dioxide, or combinations thereof.

In various embodiments, the plasma 10 may be generated by applying cyclic power pulses to power electrodes in the process chamber. In some embodiments, one cycle of the cyclic power pulses may comprise a first plurality of pulses to a source power (SP) electrode and a second plurality of pulses to a bias power (BP) electrode. In some embodiments, the second plurality of pulses may be synchronized with the first plurality of pulses. These power applications may be controlled to optimize the bombardment conditions for the vertical loading effect. Various embodiments of timing diagrams for applied source and bias powers will be described in details below with reference to FIGS. 5A-5B.

As shown in FIG. 1C, the plasma 10 may bombard the pattern transfer layer 118, causing material from the pattern transfer layer 118 to be redistributed, sealing the top portions of the first and second openings 122 and 124. The pattern transfer layer 118 after bombardment may also be referred to as a modified surface layer 128 through the sputtering action of the plasma ions. In various embodiments, a top portion of the first opening 122 may be sealed as indicated by a first portion 150, while a top portion of the second opening 124 may be sealed with a second portion 152.

The bombardment may differentially seal top portions of the first and the second openings 122 and 124 based on a difference between the first width w₁ and the second width w₂. In various embodiments, the depth of sealing (e.g., depths of the first and second portions 150 and 152) may depend on the width of the opening. The first opening 122 with larger width may exhibit a deeper sealing depth (the first portion 150) compared to the second opening 124 (the second portion 152). This differential sealing occurs because larger openings allow plasma ions to penetrate deeper before the material buildup at the top creates a complete seal. The aspect ratio (height-to-width ratio) of the openings may influence how quickly the sealing occurs, with higher aspect ratio features (smaller width relative to height) sealing more quickly and with less depth than lower aspect ratio features (larger width relative to height).

FIG. 2C uses dashed lines to illustrate that all openings may be sealed by the modified surface layer 128. From the top view, the substrate 100 may be fully covered by the modified surface layer 128 (or the pattern transfer layer 118), with no visible openings remaining. The dashed lines indicate the positions of the sealed openings beneath the surface. This complete sealing creates a foundation for the subsequent removal process that may target the thinner sealing material over the smaller openings first.

FIGS. 3A and 4A illustrate a variation of the vertical loading process shown in FIGS. 1C and 2C, in accordance with one embodiment. FIG. 3A is a cross-sectional view of the substrate 100 through the line 3A-3A′ in FIG. 4A.

In FIG. 3A, instead of using plasma bombardment to modify the pattern transfer layer 118, a coating layer 302 may be deposited over the pattern transfer layer 118 to differentially seal the top portions of the two openings (122 and 124) based on a width difference between these two openings. FIG. 4A shows that the substrate 100 may be fully covered by the coating layer 302 with no visible openings remaining. Similar to the vertical loading effect described previously, the sealing depth may be deeper for a wider opening compared to a narrower opening. In various embodiments, the depth of the coating layer 302 in the first opening 122 (a first portion 350) may be greater than the depth of the coating layer 302 in the second opening 124 (a second portion 352).

The coating layer 302 may comprise various materials capable of preferentially sealing top sections of openings rather than depositing uniformly at the bottoms. Suitable materials may include silicon dioxide (SiO₂), silicon nitride (SiN), silicon oxynitride (SiON), silicon carbide (SiC), silicon oxycarbide (SiOC), titanium nitride (TiN), titanium oxide (TiO₂), amorphous silicon, or combinations thereof. These materials may be selected based on their deposition characteristics and compatibility with subsequent processing steps.

To achieve preferential top sealing effect, various deposition techniques and conditions can be controlled. In some embodiments, the coating layer 302 may be formed using physical vapor deposition (PVD), sputtering, plasma-enhanced chemical vapor deposition (PECVD), atomic layer deposition (ALD), evaporation, or other suitable deposition methods. In various embodiments, process conditions may be tuned to promote top sealing through several mechanisms: angled deposition where the incident angle of deposition species promotes material accumulation at the feature tops; rapid deposition rates that cause accelerated narrowing at opening entrances before significant material can reach the bottoms; high-pressure deposition that reduces the mean free path of deposition species; temperature control to adjust sticking coefficients; or modulation of plasma parameters to control the directionality of deposition species.

The vertical loading processes illustrated in FIGS. 1C and 3A may leverage the geometric constraints of high-aspect-ratio features to create differential sealing depths during plasma bombardment or deposition processes. This phenomenon may occur because wider openings allow deeper penetration of incoming species before sealing, while narrower openings seal more quickly and at shallower depths due to their restricted access angles and higher aspect ratios. This natural correlation between opening width and sealing depth may enable processing that preferentially exposes smaller openings first during subsequent removal steps. The vertical loading process may exhibit several advantages over conventional lateral loading techniques, including reduced alignment mark build-up, elimination of missing contacts, improved process control, enhanced pattern fidelity, and compatibility with existing equipment. By increasing the size of smaller features while maintaining the dimensions of larger ones, this technique may effectively reduce local critical dimension variations in advanced semiconductor manufacturing.

FIG. 1D illustrates a cross-sectional view of the substrate 100 through the line 1D-1D′ in FIG. 2D, showing the next step in the process following the vertical loading process demonstrated in FIG. 1C. In this step, an encapsulating layer 130 may be formed over the modified surface layer 128 to cover the substrate 100 as shown in FIG. 2D.

In some embodiments, the encapsulating layer 130 may comprise materials same with the modified surface layer 128. In alternative embodiments, the encapsulating layer 130 may comprise different materials from the modified surface layer 128. The encapsulating layer 130 may comprise deposition techniques and materials similar to those described for the coating layer 302 in FIG. 3A.

In some embodiments, the encapsulating layer 130 may enhance the planarization of the substrate surface, creating a more uniform starting point for the subsequent removal process. In some embodiments, the encapsulating layer 130 may ensure the sealing created by the vertical loading process, maintaining the depth difference between the sealing of the first opening 122 and the second opening 124. The encapsulating layer 130 may improve the LCDU reduction effect. As the surface becomes more planar, the removal process becomes more predictable and controllable, leading to more consistent CD adjustment across the substrate.

In some embodiments, a planarization process using chemical mechanical polishing (CMP) may be applied to the substrate 100 after deposition of the encapsulating layer 130 to ensure a completely flat surface. The planarization process may mechanically and chemically remove excess material from the encapsulating layer 130, creating a planar surface across the entire substrate 100. By achieving enhanced planarity, the planarization process may further improve the uniformity of the subsequent removal process, enabling more precise control over the selective exposure of smaller openings. This optional planarization process may be particularly beneficial for substrates with tight LCDU control requirement. The flat surface resulting from the planarization process ensures that the depth difference between the sealing of different-sized openings is preserved while eliminating any surface irregularities that could affect the uniformity of the subsequent removal process.

FIGS. 1E through 1I and their corresponding top views in FIGS. 2E through 2I illustrate different stages of a removal process used to expose and widen openings to reduce LCDU, in accordance with various embodiments.

The removal process may employ various techniques depending on the specific materials and process requirements. These techniques include reactive ion etching (RIE), inductively coupled plasma (ICP) etching, capacitively coupled plasma (CCP) etching, downstream plasma etching, remote plasma etching, atomic layer etching (ALE), chemical dry etching (CDE), isotropic wet etching using acid or base solutions, vapor phase etching, or combinations thereof. The specific etch chemistry is selected based on the materials being removed and the desired etch profile.

In accordance with one embodiment, FIGS. 1E and 2E show an initial stage of the removal process, where an etch gas 12 may be flowed into the process chamber containing the substrate 100. In some embodiments, a plasma may be generated by applying a source power to ionize the etch gas 12, creating reactive species that facilitate the removal process. The etching process may begin to remove the encapsulating layer 130 and portions of the modified surface layer 128, gradually exposing the top sealing portions in the openings (e.g., the first and second portions 150 and 152) as shown in the top view of FIG. 2E. The dashed lines in FIG. 2E represent that the two openings (122 and 124) may be still sealed by the modified surface layer 128.

In various embodiments, the etch gas 12 may comprise fluorine-containing gases (such as CF₄, CHF₃, C₂F₆, SF₆, NF₃), chlorine-containing gases (such as Cl₂, BCl₃, HCl), oxygen-containing gases (such as O₂, CO, CO₂), hydrogen-containing gases (such as H₂, NH₃, CH₄), inert gases (such as Ar, He, Ne), or combinations thereof. The process parameters, including gas flow rates, pressure, temperature, power levels, and process duration, may be optimized to achieve the desired removal rate and selectivity.

In some embodiments, the removal process may be performed in multiple steps with different chemistries or conditions to optimize the exposure of smaller openings while maintaining seals over larger openings. For example, an initial step may use a more isotropic etch to remove the top layers uniformly, followed by an etch that preferentially removes material from smaller openings.

In some embodiments, the removal process may also utilize non-plasma techniques such as chemical etching, where reactive chemicals selectively dissolve the target materials without plasma activation. In alternative embodiments, mechanical removal methods such as ion beam etching or sputtering may be employed, particularly when highly directional removal is desired.

In FIG. 1F, which shows the cross-sectional view through line 1F-1F′ in FIG. 2F, the removal process may remove the second portion 152 and expose the second opening 124, while the first opening 122 remains sealed by remaining portions of the modified surface layer 128. The top view in FIG. 2F illustrates this selective exposure, where the second opening 124 exposes the layer to-be-etched 104, while the first opening 122 is shown with a dashed line indicating it remains sealed beneath the remaining portions of the modified surface layer 128. This differential exposure may create the opportunity for the subsequent widening of the smaller opening (e.g., the second opening 124) through continued removal processing.

In various embodiments, the selective exposure is a direct result of the vertical loading process established in earlier steps. As explained previously, the second opening 124 may comprise a shallower sealing depth (shown as the second portion 152 in FIG. 1C) compared to the first opening 122 (shown as the first portion 150 in FIG. 1C). Consequently, as the removal process progresses uniformly from the top surface downward, it reaches and breaks through the sealing material in the second opening 124 first, while the deeper sealing material in the first opening 122 remains intact.

Now refer to FIGS. 3B and 4B, which illustrate similar removal process following a variation of the vertical loading process shown in FIGS. 3A and 4A.

In FIG. 3B, a removal process similar to that described for FIG. 1F may be applied to the substrate 100. In various embodiments, an etch gas 32, which may have similar composition to the etch gas 12 previously described, may be introduced to remove portions of the coating layer 302. Due to the differential sealing depths created by the vertical loading process during coating layer deposition, the removal process may expose the second opening 124 first while maintaining the seal over the first opening 122. The top view in FIG. 4B corresponds to the cross-sectional view in FIG. 3B, showing that the second opening 124 is exposed (solid line) while the first opening 122 remains sealed (dashed line).

In one or more embodiments, following exposure of the second opening 124, the removal process may continue to widen the second opening 124 in a manner analogous to that shown in FIGS. 1G through 1I as will be described in detail below.

FIGS. 1G and 2G illustrate the step of widening of the smaller opening after its exposure in previous step. In FIG. 1G, which presents the cross-sectional view through line 1G-1G′ in FIG. 2G, the removal process may continue etching the planarization layer 116 to widen the second opening 124.

In various embodiments, the removal process may etch sidewalls and bottom of the exposed second opening 124, gradually increasing its width from the original second width w₂ to a third width w₃. During the removal process, the first opening 122 may remain sealed by the remaining portions of the modified surface layer 128, protecting it from any dimensional changes. The top view in FIG. 2G shows that the second opening 124 is larger (with width w₃) compared to its original size, while the first opening 122 may remain sealed beneath the modified surface layer 128 (indicated by a dashed line).

In various embodiments, a difference between the third width w₃ and the first width w₁ is smaller than a difference between the second width w₂ and the first width w₁. By increasing only the smaller dimensions while maintaining the larger ones, the removal process may reduce the critical dimension variation between features, bringing all features closer to the target dimension.

FIG. 1H presents the cross-sectional view through line 1H-1H′ in FIG. 2H, where the removal process may remove remaining portion of the modified surface layer 128 sealing the first opening 122. As a result, both the first opening 122 and the second opening 124 (now widened to the third width w₃) may be fully exposed.

The cross-sectional view in FIG. 1H and top view in FIG. 2H show that both openings (122 and 124) may expose the top surface of the layer to-be-etched 104, with no remaining sealing material from the modified surface layer 128. The first opening 122 may maintain original width, while the second opening 124 may exhibit increased width to the third width w₃ through the widening process in the previous step. The planarization layer 116 may comprise openings with more uniform dimensions than the original pattern, reflecting the LCDU improvement achieved through the vertical loading process. The planarization layer 116 after the removal process may also be referred to as a modified planarization layer 126.

FIGS. 1I and 2I illustrate a step where the improved pattern in the modified planarization layer 126 is transferred into the layer to-be-etched 104. In FIG. 1I, which presents the cross-sectional view through line 1I-1I′ in FIG. 2I, the modified planarization layer 126 may serve as an etch mask for patterning the underlying layer to-be-etched 104. The etching process may extend both openings 122 and 124 completely through the layer to-be-etched 104, exposing a top surface of the substrate layer 102.

The etching process used to pattern the layer to-be-etched 104 may employ similar techniques to those described for the removal process earlier, including reactive ion etching (RIE), inductively coupled plasma (ICP) etching, or other suitable methods. In various embodiments, the etch chemistry and parameters may specifically optimized for the material composition of the layer to-be-etched 104, which may be a dielectric material such as silicon nitride (SiN), silicon oxide (SiO₂), or other materials.

In various embodiments, following the completion of the pattern transfer process shown in FIG. 1I, a metal deposition process may be performed to fill the two openings 122 and 124, creating conductive vias or contacts that provide electrical connections between different layers of the semiconductor device. The metal filling may comprise various conductive materials including copper (Cu), tungsten (W), aluminum (Al), cobalt (Co), ruthenium (Ru), molybdenum (Mo), titanium (Ti), tantalum (Ta), nickel (Ni), their alloys, or combinations thereof. In some embodiments, the metal deposition may be preceded by the formation of barrier and/or liner layers such as titanium nitride (TiN), tantalum nitride (TaN), or tungsten nitride (WN) to prevent metal diffusion into the surrounding dielectric material. The metal deposition may be performed using various techniques including physical vapor deposition (PVD), chemical vapor deposition (CVD), atomic layer deposition (ALD), electroplating, electroless plating, or combinations thereof. Following the metal deposition, a planarization process such as chemical mechanical polishing (CMP) may be performed to remove excess metal material from the top surface of the substrate 100, creating isolated metal-filled vias or contacts with improved uniformity due to the enhanced LCDU achieved through the vertical loading process, thereby ensuring more consistent electrical performance across the device.

While FIGS. 2A-2I and 4A-4B depict the openings 122 and 124 with circular shapes representative of via or contact hole patterns in semiconductor manufacturing, it should be understood that the vertical loading approach for LCDU improvement is not limited to circular features. In various embodiments, the openings may take different geometrical forms such as rectangles, squares, ovals, ellipses, or other polygonal shapes depending on the specific device requirements and design rules. The fundamental principles of the vertical loading effect apply regardless of the opening shape, as the differential sealing based on feature size relies primarily on the aspect ratio and width differences rather than the specific geometry. This versatility allows the disclosed method to be applied across a wide range of semiconductor device structures, including but not limited to trenches, slots, and various interconnect patterns where local critical dimension uniformity is essential for proper device functionality and performance.

Although FIGS. 1A-1I, 2A-2I, 3A-3B, 4A-4B illustrate only two openings (e.g., the first opening 122 and the second opening 124) for clarity and simplicity of explanation, it should be understood that the vertical loading approach can be applied to a plurality of openings with various dimensions across the substrate. In practical semiconductor manufacturing scenarios, a single substrate may contain thousands or millions of openings with a distribution of widths that contribute to the overall LCDU calculation. The principles and processes described herein apply equally to scenarios with multiple openings of different sizes, where the vertical loading effect may differentially seal these openings based on their respective widths, allowing for exposure and widening of smaller openings while maintaining seals over larger ones. This scalability makes the disclosed method particularly valuable for addressing LCDU challenges in high-volume manufacturing environments where critical dimension control must be maintained across numerous features simultaneously.

While FIGS. 1A-1I, 2A-2I, 3A-3B, and 4A-4B provide illustrations of steps during the vertical loading process for LCDU improvement, several non-illustrated intermediate steps or variations may be implemented within the disclosed framework. These may include pre-treatment steps such as surface conditioning or cleaning prior to the vertical loading process; in-situ monitoring techniques to determine optimal endpoint detection during the sealing or removal processes; multiple cycles of partial sealing and removal to achieve more precise CD control; implementation of thermal treatments between process steps to stabilize materials or enhance selectivity; application of bias tuning during plasma processes to optimize directionality; variations in gas composition ratios throughout the process to enhance selectivity or control etch profiles; integration of metrology steps between illustrated stages to provide feedback for process adjustment; post-metal deposition annealing to improve electrical characteristics; implementation of gradient or pulse modulated processes rather than constant parameters; and various hardware configurations to optimize plasma distribution or gas flow patterns. Additionally, the illustrated process may be integrated within a larger manufacturing sequence that includes multiple lithography, etching, and deposition steps to create complex multi-layer semiconductor devices. These non-illustrated aspects provide flexibility in implementing the vertical loading concept across different manufacturing environments while maintaining the core principles of differential sealing and selective dimensional adjustment to improve LCDU.

FIGS. 5A-5B illustrate schematic timing diagrams for source power (SP) and bias power (BP) during the plasma bombardment process described with reference to FIG. 1C, in accordance with various embodiments.

Referring to FIG. 5A, a schematic timing diagram includes source power and bias power over time is illustrated, showing a complete cycle 560 of the process, in accordance with an embodiment. The cycle 560 may be an advanced pulsing technique (APT) applied to a capacitively coupled plasma (CCP) system or an inductively coupled plasma (ICP) system. In various embodiments, the cycle 560 may be repeatedly performed (e.g. cyclically). For example, the cycle 560 may be performed many times (e.g. >>1), the exact number of times depending on the specific objectives of a chosen plasma process. In various embodiments, the source power may be a RF source power.

In a first time duration 510, a first power pulse 512 may be applied to a SP electrode in a duration between 1 μs and 10 ms. In various embodiments, the first power pulse 512 may comprise a plurality of power pulses. In various embodiments, the first power pulse 512 may comprise radio frequency pulses. In some embodiments, the first power pulse 512 may comprise a waveform of rectangular shape with a first SP level. The first power pulse 512 may generate a stable plasma by ionizing the process gas described with reference to FIG. 1C in the process chamber.

In a second time duration 520, a second power pulse 516 may be applied to a BP electrode. In various embodiments, the second power pulse 516 may comprise a plurality of power pulses. In some embodiments, the second power pulse 516 may comprise a waveform of rectangular shape with a first BP level. The bias power may comprise a RF bias power, with a frequency of the RF bias power being synchronized with a frequency of the RF source power in various embodiments. This synchronization may enhance plasma ion energy control and directionality, improving the differential sealing effect where larger openings receive deeper material deposition. In one or more embodiments, the bias power may be between 10 W and 1000 W, for example, 50 W, providing sufficient ion energy for effective bombardment while maintaining controlled material redistribution. The bias power may create a voltage bias that accelerates ions toward the substrate surface, with the bombardment causing material from the pattern transfer layer 118 to be sputtered and redeposited to differentially seal the openings based on their respective widths.

In various embodiments, the first time duration 510 and the second time duration 520 may be fully or partially overlapping, allowing simultaneous application of source and bias power for enhanced plasma density and ion directionality. In other embodiments, there may be a time gap between the end of first time duration 510 and the beginning of second time duration 520, creating a sequential power application that can help manage plasma instabilities or reduce wafer charging effects.

Following the first time duration 510, a third time duration 530 may occur during which the source power may be lowered or completely turned off during the plasma bombardment process shown in FIG. 1C. In various embodiments, the SP electrode may be coupled to a first reference potential node 514 coupled to a first reference potential. The first reference potential may be lower than the first SP level, reducing the plasma density for improved control over the ion energetics in the plasma for controlled bombardment of the pattern transfer layer 118. In some embodiments, the first reference potential node 514 may be floating. The third time duration 530 may help control plasma density and temperature, preventing excessive heating or unwanted chemical reactions that could affect the differential sealing of the first and second openings 122 and 124.

In a fourth time duration 540, the bias power level may be lowered or turned off during the plasma bombardment process. In various embodiments, the BP electrode may be coupled to a second reference potential node 518 coupled to a second reference potential, which may be lower than the first BP level. The fourth time duration 540 may follow sequentially with the second time duration 520. In some embodiments, the second reference potential may be floating. The second reference potential node 518, combined with the first reference potential node 514, enables effective control of the ion flux and energy during the bombardment process. The cyclic modulation of plasma density and ion energy facilitates precise control over the sputtering and redeposition of material from the pattern transfer layer 118 to form the modified surface layer 128 with differential sealing depths in openings of different widths. This pulsed power approach allows for fine-tuning of the vertical loading process to optimize LCDU improvement.

While FIG. 5A illustrates a cycle comprising four time durations (first time duration 510, second time duration 520, third time duration 530, and fourth time duration 540), it should be understood that the number of time durations in a cycle may vary in different embodiments of the plasma bombardment process shown in FIG. 1C. Some implementations may utilize fewer time durations, such as a two-time duration or three-time duration cycle, while others may incorporate additional time durations for more nuanced control over the bombardment process that forms the modified surface layer 128. Furthermore, the timing and synchronization of the SP and BP pulses may be adjusted based on specific requirements for differential sealing of openings. For example, the first power pulse 512 and the second power pulse 516 may be asynchronized to create specific ion energy distributions that optimize material redistribution from the pattern transfer layer 118. In other embodiments, the first power pulse 512 and the second power pulse 516 may be synchronized to occur simultaneously, enhancing directional bombardment while controlling the lateral spread of sputtered material. The power levels of both SP and BP can also have multiple combinations beyond those shown in FIG. 5A. These combinations may include graduated power levels that change with bombardment duration, multiple high and low power states within a single cycle to separately optimize sputtering and redeposition phases, or more complex waveforms designed to balance the vertical loading effect across different opening widths. This flexibility in power application allows for precise control over the plasma characteristics, enabling optimization of the bombardment process for different pattern transfer layer materials (e.g., SiARC, LTO, or other silicon-based materials), feature geometries (varying aspect ratios), and specific objectives such as sealing depth control or LCDU improvement maximization.

FIG. 5B illustrates an alternative power application scheme for the plasma bombardment process shown in FIG. 1C, where the source power follows a pulsed pattern similar to FIG. 5A, while the bias power is supplied as a constant direct current (DC). In this configuration, the source power maintains its cyclic nature with the first power pulse 512 applied during the first time duration 510, followed by reduced or zero power during the third time duration 530. This pulsed approach to source power continues to provide control over plasma density and argon ion generation for bombarding the pattern transfer layer 118. However, unlike the pulsed bias power shown in FIG. 5A, the bias power in FIG. 5B may be applied as a continuous DC bias with a constant voltage throughout the bombardment process. This constant DC bias may provide uninterrupted ion acceleration toward the substrate surface, resulting in consistent bombardment energy for material redistribution. The DC bias voltage may be set to an appropriate level to ensure sufficient ion energy for effective directional bombardment while controlling the depth of the modified surface layer 128 in openings of different widths. This approach may provide process simplicity and more stable ion energy distribution compared to RF bias configurations. The constant DC bias may be particularly beneficial for maintaining consistent bombardment directionality throughout the process cycle, even during periods of lower source power.

In various embodiments, the power application schemes illustrated in FIGS. 5A and 5B may be combined or alternated during different stages of the bombardment process to optimize the vertical loading process. For example, the process might begin with the RF bias configuration shown in FIG. 5A to establish initial differential sealing with precise control over ion energy distribution, then transition to the DC bias approach shown in FIG. 5B for consistent directional bombardment as the modified surface layer 128 forms. Alternatively, the two power schemes may be alternated in a programmed sequence to address changing conditions as the sealing depth increases in different width openings. In some embodiments, elements from both schemes may be integrated, such as using pulsed RF bias power with underlying DC offset voltage to combine the benefits of both approaches. This hybrid approach may provide the energy distribution control of RF bias power while maintaining a minimum ion acceleration from the DC component, allowing for fine-tuning of the differential sealing process that creates deeper sealing in the larger openings compared to smaller openings, which is essential for the subsequent selective exposure and widening steps that improve LCDU.

FIG. 6 illustrates experimental data demonstrating the effectiveness of the vertical loading process in reducing LCDU across different process durations, in accordance with one embodiment. In FIG. 6, mean critical dimension (CD) 602 is represented by bars and measured on the right vertical axis in nm, and LCDU 604 is represented by circle markers and measured on the left vertical axis in nm. The horizontal axis shows the duration of plasma bombardment in seconds.

The data reveals reduction of the mean CD 602 and improvement of the LCDU 604 as the bombardment duration increases. Using argon gas as the process gas for plasma bombardment, the graph shows progressive LCDU reduction across multiple time points. In one or more embodiments, the baseline condition shows the highest LCDU value, which steadily decreases as the argon bombardment duration increases through 94 s, 141 s, 188 s, 235 s, and 282 s (from left to right in FIG. 6). In one embodiment, optimal results may be achieved after 188 seconds of bombardment, which improved LCDU by approximately 23% at a mean CD of approximately 10 nm. The data demonstrates that the effectiveness of vertical loading process in addressing LCDU challenges in advanced semiconductor manufacturing.

FIG. 7 illustrates a flow diagram of a method for improving local critical dimension uniformity in semiconductor device manufacturing using a vertical loading process, in accordance with an embodiment.

At block 702, a substrate may be provided in a process chamber. The substrate may be same to the substrate 100 as described with reference to FIG. 1A. In various embodiments, the substrate may comprise a planarization layer disposed over a layer to-be-etched, a pattern transfer layer disposed over the planarization layer, and a patterned photoresist layer disposed over the pattern transfer layer. In some embodiments, the planarization layer may comprise materials such as organic planarization layer (OPL), amorphous carbon layer (ACL), or other carbon-containing materials as described previously. The pattern transfer layer may comprise materials such as silicon anti-reflective coating (SiARC), low temperature oxide (LTO), or other silicon-containing materials. The layer to-be-etched may comprise dielectric materials such as silicon nitride (SiN), silicon oxide (SiO₂), or other materials targeted for patterning.

At block 704, a plurality of openings may be formed through the pattern transfer layer and the planarization layer. This process may correspond to the etching process described with reference to FIGS. 1B and 2B. The plurality of openings may comprise a first opening with a first width and a second opening with a second width, wherein the first width may be different from the second width. In some embodiments, the first width may be greater than the second width. In various embodiments, the openings may be formed using reactive ion etching (RIE), inductively coupled plasma (ICP) etching, or other suitable etching techniques as described previously.

At block 706, a process gas may be flowed in the process chamber and a radio frequency source power may be applied to generate plasma from the process gas. The process gas may comprise an inert gas such as argon, helium, neon, krypton, xenon, nitrogen, or combinations thereof as described in reference to FIG. 1C. In various embodiments, the plasma generation may involve applying cyclic power pulses as illustrated in FIGS. 5A and 5B, with synchronized source power and bias power applications.

At block 708, the pattern transfer layer may be bombarded with the plasma to form a modified surface layer that differentially seals top portions of the first and the second openings. This process may correspond to the bombardment process described with reference to FIGS. 1C and 2C. In various embodiments, the bombardment may cause material from the pattern transfer layer to be sputtered and redeposited, forming the modified surface layer 128. In various embodiments, the vertical loading effect may result in a deeper seal in the first opening compared to the second opening due to the difference in opening widths.

At block 710, an encapsulating layer may be formed over the modified surface layer. This process may correspond to the encapsulating layer formation described with reference to FIGS. 1D and 2D. In various embodiments, the encapsulating layer may comprise similar materials as the modified surface layer or different materials such as those described for the coating layer 302 in FIGS. 3A and 3B. The encapsulating layer may help create a more planar surface and enhance the differential sealing effect.

At block 712, a removal process may be performed that removes portions of the modified surface layer sealing the second opening while maintaining the seal over the first opening. This process may correspond to the removal process described with reference to FIGS. 1E, 1F, 2E, and 2F. The removal process may utilize various techniques including reactive ion etching, chemical dry etching, wet etching, or other methods as described previously.

At block 714, the removal process may be continued to increase the second width of the second opening to a third width, wherein a difference between the third width and the first width may be less than a difference between the second width and the first width, thereby reducing critical dimension variation. This process may correspond to the widening of the smaller opening described with reference to FIGS. 1G and 2G. The reduction in width difference directly translates to improved LCDU, as demonstrated by the experimental data in FIG. 6 showing 23% LCDU improvement at approximately 10 nm CD.

FIG. 8 illustrates a flow diagram of an alternative method for improving LCDU in semiconductor device manufacturing using a deposition based vertical loading process, in accordance with an embodiment.

At block 802, a substrate may be provided in a process chamber. The substrate may be similar to the substrate 100 as described with reference to FIG. 1A. In various embodiments, the substrate may comprise a planarization layer disposed over a layer to-be-etched, a pattern transfer layer disposed over the planarization layer, and a patterned photoresist layer disposed over the pattern transfer layer. In some embodiments, the planarization layer may comprise materials such as organic planarization layer (OPL), amorphous carbon layer (ACL), or other carbon-containing materials as described previously. The pattern transfer layer may comprise materials such as silicon anti-reflective coating (SiARC), low temperature oxide (LTO), or other silicon-containing materials. The layer to-be-etched may comprise dielectric materials such as silicon nitride (SiN), silicon oxide (SiO₂), or other materials targeted for patterning.

At block 804, a plurality of openings may be formed through the pattern transfer layer and the planarization layer. This process may correspond to the etching process described with reference to FIGS. 1B and 2B. The plurality of openings may comprise a first opening with a first width and a second opening with a second width, wherein the first width may be different from the second width. In some embodiments, the first width may be greater than the second width. In various embodiments, the openings may be formed using reactive ion etching (RIE), inductively coupled plasma (ICP) etching, or other suitable etching techniques as described previously.

At block 806, a coating layer may be formed over the pattern transfer layer, wherein the coating layer differentially seals top portions of the first and the second openings based on width difference between the first and the second openings. In various embodiments, a depth of the coating layer in the first opening may be greater than a depth of the coating layer in the second opening. This process may correspond to the coating layer formation described with reference to FIGS. 3A and 4A. In various embodiments, the coating layer may comprise materials such as silicon dioxide (SiO2), silicon nitride (SiN), silicon oxynitride (SiON), silicon carbide (SiC), silicon oxycarbide (SiOC), titanium nitride (TiN), titanium oxide (TiO₂), amorphous silicon, or combinations thereof. The coating layer may be formed using deposition techniques and conditions as described previously with reference to FIGS. 3A and 4A.

At block 808, portions of the coating layer may be removed to expose the second opening while maintaining a seal over the first opening. This process may correspond to the removal process described with reference to FIGS. 3B and 4B, which show the exposure of the smaller opening while the larger opening remains sealed. The removal process may utilize various techniques including reactive ion etching, chemical dry etching, wet etching, or other methods as described previously in relation to the removal processes shown in FIGS. 1F and 2F.

At block 810, the second width of the second opening may be increased to a third width, wherein a difference between the third width and the first width may be less than a difference between the second width and the first width, thereby reducing critical dimension variation. This process may correspond to the widening of the smaller opening described with reference to FIGS. 1G and 2G, following the alternative sealing approach of FIGS. 3A-3B and 4A-4B. The continued removal process may widen the smaller opening while the larger opening remains protected by the deeper coating layer seal, resulting in reduced critical dimension variation between openings.

This flow diagram encapsulates the key steps of the alternative deposition-based vertical loading approach for LCDU improvement, providing another systematic method for reducing critical dimension variations in semiconductor device manufacturing. This approach achieves similar LCDU improvement results as the plasma bombardment method shown in FIG. 7, but utilizes a different mechanism for creating the differential sealing depths that enable selective processing of smaller openings.

In various embodiments, following the processes outlined in FIGS. 7 and 8, several additional steps may be performed, though not explicitly shown in the flowcharts. After achieving the improved LCDU through the vertical loading approach, the process may continue with etching the layer to-be-etched through the openings with reduced CD variation, as illustrated in FIGS. 1H-1I. This etching step may utilize similar techniques as described for the removal process but optimized for the specific material of the layer to-be-etched. Following the etching of the layer to-be-etched, metal deposition may be performed to fill the openings, creating conductive vias or contacts. The metal filling may comprise various conductive materials including copper, tungsten, aluminum, cobalt, ruthenium, or their alloys, and may be preceded by the formation of barrier and/or liner layers. Additional intermediate steps may include in-situ cleaning processes before metal deposition, annealing treatments to improve material properties, planarization processes such as chemical mechanical polishing to remove excess material, and various metrology or inspection steps to verify dimensional control. In some embodiments, multiple cycles of the vertical loading process may be implemented with varying parameters to achieve optimal LCDU improvement. Furthermore, the methods described in FIGS. 7 and 8 may be integrated within a larger process flow involving multiple patterning, etching, and deposition steps to create complex multilayer semiconductor devices with enhanced performance characteristics resulting from the improved critical dimension uniformity.

While the inventive aspects are described primarily in the context of improving local critical dimension uniformity in semiconductor via and contact hole patterning, it should also be appreciated that these inventive aspects may also apply to various semiconductor fabrication processes requiring precise dimensional control. In particular, aspects of this disclosure may similarly apply to trench formation for metal lines, gate patterning in transistor fabrication, fin formation in FinFET devices, through-silicon via (TSV) creation in 3D integration, memory cell patterning, MEMS device fabrication, and photonic device manufacturing where dimensional uniformity is required for performance.

Example embodiments of the invention are described below. Other embodiments can also be understood from the entirety of the specification as well as the claims filed herein.

Example 1. A method for processing a substrate, the method including: providing a substrate in a process chamber, the substrate including a layer to-be-etched, a planarization layer disposed over the layer to-be-etched, and a pattern transfer layer disposed over the planarization layer; forming a plurality of openings through the pattern transfer layer and the planarization layer, the plurality of openings including a first opening with a first width and a second opening with a second width, the first width being different from the second width; flowing a process gas in the process chamber and applying a radio frequency (RF) source power to generate a plasma from the process gas; bombarding the pattern transfer layer with the plasma to form a modified surface layer that differentially seals top portions of the first and the second openings based on a difference between the first width and the second width; etching the modified surface layer to expose the second opening while maintaining a seal over the first opening; and continuing the etching to increase the second width of the second opening to a third width, where a difference between the third width and the first width is less than a difference between the second width and the first width.

Example 2. The method of example 1, where continuing the etching further includes removing all remaining portions of the modified surface layer to expose the first opening, where the etching converts the planarization layer to a modified planarization layer.

Example 3. The method of one of examples 1 or 2, further including etching the layer to-be-etched using the modified planarization layer as an etch mask.

Example 4. The method of one of examples 1 to 3, further including forming an encapsulating layer over the modified surface layer after the bombarding and before the etching.

Example 5. The method of one of examples 1 to 4, where the process gas includes argon, nitrogen, or carbon dioxide.

Example 6. The method of one of examples 1 to 5, where a depth of the modified surface layer in the first opening is greater than a depth of the modified surface layer in the second opening.

Example 7. The method of one of examples 1 to 6, where the pattern transfer layer includes silicon anti-reflective coating (SiARC), organic anti-reflective coating, silicon oxide (SiO2), silicon nitride (SiN), silicon oxynitride (SiON), silicon carbide (SiC), silicon oxycarbide (SiOC), or titanium nitride (TiN).

Example 8. The method of one of examples 1 to 7, where the planarization layer includes organic planarization layer (OPL), amorphous carbon layer (ACL), spin-on carbon (SOC), or organic layer.

Example 9. The method of one of examples 1 to 8, further including applying a bias power to the substrate while applying the RF source power.

Example 10. The method of one of examples 1 to 9, where the bias power includes RF bias power or direct current (DC) bias power.

Example 11. A method for processing a substrate, the method including: providing a substrate including a pattern transfer layer disposed over a planarization layer, where the pattern transfer layer and the planarization layer include a first opening and a second opening extending through, the first opening including a first width and the second opening including a second width, where the first width is greater than the second width; forming a coating layer over the pattern transfer layer, where the coating layer differentially seals top portions of the first and the second openings, and where a depth of the coating layer in the first opening is greater than a depth of the coating layer in the second opening; removing portions of the coating layer to expose the second opening while maintaining a seal over the first opening; and continuing the removing to increase the second width of the second opening to a third width, where a difference between the third width and the first width is less than a difference between the second width and the first width.

Example 12. The method of example 11, where continuing the removing further includes removing all remaining portions of the coating layer to expose the first opening, where the removing converts the planarization layer to a modified planarization layer.

Example 13. The method of one of examples 11 or 12, where the substrate further includes a layer to-be-etched disposed beneath the planarization layer, and the method further includes etching the layer to-be-etched using the modified planarization layer as an etch mask.

Example 14. The method of one of examples 11 to 13, where the pattern transfer layer includes silicon anti-reflective coating (SiARC), organic anti-reflective coating, silicon oxide (SiO2), silicon nitride (SiN), silicon oxynitride (SiON), silicon carbide (SiC), silicon oxycarbide (SiOC), or titanium nitride (TiN).

Example 15. The method of one of examples 11 to 14, where the planarization layer includes organic planarization layer (OPL), amorphous carbon layer (ACL), spin-on carbon (SOC), or organic layer.

Example 16. A method for processing a substrate, the method including: loading a substrate in a process chamber, the substrate including a pattern transfer layer disposed over a planarization layer, where the pattern transfer layer and the planarization layer include a first opening and a second opening extending through, the first opening including a first width and the second opening including a second width; flowing a process gas including an inert gas into the process chamber; applying cyclic power pulses to power electrodes in the process chamber to generate a plasma from the process gas; bombarding the pattern transfer layer with the plasma to differentially seal top portions of the first and the second openings based on a difference between the first width and the second width; etching the pattern transfer layer to expose the second opening while maintaining a seal over the first opening; and continuing the etching to increase the second width of the second opening to a third width.

Example 17. The method of example 16, where a difference between the third width and the first width is less than a difference between the second width and the first width.

Example 18. The method of one of examples 16 or 17, where the substrate further includes a layer to-be-etched disposed beneath the planarization layer, and the method further includes etching the layer to-be-etched through the first opening and the second opening.

Example 19. The method of one of examples 16 to 18, where the inert gas includes argon, nitrogen, or carbon dioxide.

Example 20. The method of one of examples 16 to 19, further including disposing an encapsulating layer over the pattern transfer layer after the bombarding and before the etching.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-8 may be combined in further embodiments. It is therefore intended that the appended claims encompass any such modifications or embodiments.

What is claimed is:

1. A method for processing a substrate, the method comprising:
providing a substrate in a process chamber, the substrate comprising a layer to-be-etched, a planarization layer disposed over the layer to-be-etched, and a pattern transfer layer disposed over the planarization layer;
forming a plurality of openings through the pattern transfer layer and the planarization layer, the plurality of openings comprising a first opening with a first width and a second opening with a second width, the first width being different from the second width;
flowing a process gas in the process chamber and applying a radio frequency (RF) source power to generate a plasma from the process gas;
bombarding the pattern transfer layer with the plasma to form a modified surface layer that differentially seals top portions of the first and the second openings based on a difference between the first width and the second width;
etching the modified surface layer to expose the second opening while maintaining a seal over the first opening; and
continuing the etching to increase the second width of the second opening to a third width, wherein a difference between the third width and the first width is less than a difference between the second width and the first width.

2. The method of claim 1, wherein continuing the etching further comprises removing all remaining portions of the modified surface layer to expose the first opening, wherein the etching converts the planarization layer to a modified planarization layer.

3. The method of claim 2, further comprising etching the layer to-be-etched using the modified planarization layer as an etch mask.

4. The method of claim 1, further comprising forming an encapsulating layer over the modified surface layer after the bombarding and before the etching.

5. The method of claim 1, wherein the process gas comprises argon, nitrogen, or carbon dioxide.

6. The method of claim 1, wherein a depth of the modified surface layer in the first opening is greater than a depth of the modified surface layer in the second opening.

7. The method of claim 1, wherein the pattern transfer layer comprises silicon anti-reflective coating (SiARC), organic anti-reflective coating, silicon oxide (SiO₂), silicon nitride (SiN), silicon oxynitride (SiON), silicon carbide (SiC), silicon oxycarbide (SiOC), or titanium nitride (TiN).

8. The method of claim 1, wherein the planarization layer comprises organic planarization layer (OPL), amorphous carbon layer (ACL), spin-on carbon (SOC), or organic layer.

9. The method of claim 1, further comprising applying a bias power to the substrate while applying the RF source power.

10. The method of claim 9, wherein the bias power comprises RF bias power or direct current (DC) bias power.

11. A method for processing a substrate, the method comprising:
providing a substrate comprising a pattern transfer layer disposed over a planarization layer, wherein the pattern transfer layer and the planarization layer comprise a first opening and a second opening extending through, the first opening comprising a first width and the second opening comprising a second width, wherein the first width is greater than the second width;
forming a coating layer over the pattern transfer layer, wherein the coating layer differentially seals top portions of the first and the second openings, and wherein a depth of the coating layer in the first opening is greater than a depth of the coating layer in the second opening;
removing portions of the coating layer to expose the second opening while maintaining a seal over the first opening; and
continuing the removing to increase the second width of the second opening to a third width, wherein a difference between the third width and the first width is less than a difference between the second width and the first width.

12. The method of claim 11, wherein continuing the removing further comprises removing all remaining portions of the coating layer to expose the first opening, wherein the removing converts the planarization layer to a modified planarization layer.

13. The method of claim 12, wherein the substrate further comprises a layer to-be-etched disposed beneath the planarization layer, and the method further comprises etching the layer to-be-etched using the modified planarization layer as an etch mask.

14. The method of claim 11, wherein the pattern transfer layer comprises silicon anti-reflective coating (SiARC), organic anti-reflective coating, silicon oxide (SiO₂), silicon nitride (SiN), silicon oxynitride (SiON), silicon carbide (SiC), silicon oxycarbide (SiOC), or titanium nitride (TiN).

15. The method of claim 11, wherein the planarization layer comprises organic planarization layer (OPL), amorphous carbon layer (ACL), spin-on carbon (SOC), or organic layer.

16. A method for processing a substrate, the method comprising:
loading a substrate in a process chamber, the substrate comprising a pattern transfer layer disposed over a planarization layer, wherein the pattern transfer layer and the planarization layer comprise a first opening and a second opening extending through, the first opening comprising a first width and the second opening comprising a second width;
flowing a process gas comprising an inert gas into the process chamber;
applying cyclic power pulses to power electrodes in the process chamber to generate a plasma from the process gas;
bombarding the pattern transfer layer with the plasma to differentially seal top portions of the first and the second openings based on a difference between the first width and the second width;
etching the pattern transfer layer to expose the second opening while maintaining a seal over the first opening; and
continuing the etching to increase the second width of the second opening to a third width.

17. The method of claim 16, wherein a difference between the third width and the first width is less than a difference between the second width and the first width.

18. The method of claim 16, wherein the substrate further comprises a layer to-be-etched disposed beneath the planarization layer, and the method further comprises etching the layer to-be-etched through the first opening and the second opening.

19. The method of claim 16, wherein the inert gas comprises argon, nitrogen, or carbon dioxide.

20. The method of claim 16, further comprising disposing an encapsulating layer over the pattern transfer layer after the bombarding and before the etching.
